(19) United States
(12) Patent Application Publication
(10) Pub. No.: US 2016/0172536 A1
(43) Pub. Date: Jun. 16, 2016

(54) SEMICONDUCTOR LIGHT-EMITTING STRUCTURE

(71) Applicant: Industrial Technology Research Institute, Hsinchu (TW)

(72) Inventors: Chia-Lung Tsai, Kaohsiung City (TW); Yen-Hsiang Fang, New Taipei City (TW); Pao-Chu Tzeng, Hsinchu County (TW)

(21) Appl. No.: 14/583,775

(22) Filed: Dec. 29, 2014

(30) Foreign Application Priority Data
Dec. 10, 2014 (TW) 103143016

(51) Int. Cl. H01L 33/14; H01L 33/06; H01L 33/38

(52) U.S. Cl. CPC H01L 33/14; H01L 33/38; H01L 33/06

(57) ABSTRACT

A semiconductor light-emitting structure including a first-type doped semiconductor layer, a second-type doped semiconductor layer, a light-emitting layer, a first electrode, a second electrode, and a magnetic layer is provided. The light-emitting layer is disposed between the first-type doped semiconductor layer and the second-type doped semiconductor layer. The first electrode is electrically connected to the first-type doped semiconductor layer, and the second electrode is electrically connected to the second-type doped semiconductor layer. The magnetic layer connects the first electrode and the first-type doped semiconductor layer. At least a portion of the magnetic layer is magnetic, and the bandgap of at least another portion of the magnetic layer is greater than 0 eV and is less than or equal to 5 eV. The material of the magnetic layer includes metal, metal oxide, or a combination thereof.

### CROSS-REFERENCE TO RELATED APPLICATION

This application claims the priority benefit of Taiwan application serial no. 103143016, filed on Dec. 10, 2014. The entirety of the above-mentioned patent application is hereby incorporated by reference herein and made a part of this specification.

### TECHNICAL FIELD

The disclosure relates to a semiconductor light-emitting structure.

### BACKGROUND

Currently, with the world's major light-emitting diode (LED) manufacturing companies all competing in the lighting market, an object of development of the manufacturing companies is to increase luminous efficiency and reduce power consumption. The luminous efficiency (such as external quantum efficiency (EQE)) of LED is the product of internal quantum efficiency (IQE) and light extraction efficiency. In the past 20 years, increasing IQE via techniques such as improving epitaxy quality and designing a quantum well structure has reached a threshold because the key factor of affecting IQE is the recombination efficiency of an electron-hole pair.

Since the mobility of an electron hole is ten times less than the mobility of an electron, and due to the quantum-confined Stark effect (QCSE) caused by a large difference in lattice constant between gallium nitride and a sapphire substrate, an overflow of electrons occurs, such that the recombination efficiency of the electron-hole pair is significantly reduced. Therefore, to increase external quantum efficiency, international manufacturers all begin with light extraction efficiency. The increase of light extraction efficiency is achieved by changing reflectance in front of and behind the light-emitting layer, or forming a complex optical design structure in back end of line. Any method used to increase light extraction efficiency increases the production time of the LED, thus affecting manufacturing cost.

### SUMMARY

A semiconductor light-emitting structure of an embodiment of the disclosure includes a first-type doped semiconductor layer, a second-type doped semiconductor layer, a light-emitting layer, a first electrode, a second electrode, and a magnetic layer. The light-emitting layer is disposed between the first-type doped semiconductor layer and the second-type doped semiconductor layer. The first electrode is electrically connected to the first-type doped semiconductor layer, and the second electrode is electrically connected to the second-type doped semiconductor layer. The magnetic layer connects the first electrode and the first-type doped semiconductor layer. At least a portion of the magnetic layer is magnetic, and the bandgap of at least another portion of the magnetic layer is greater than 0 eV and is less than or equal to 5 eV. The material of the magnetic layer includes metal, metal oxide, or a combination thereof.

A semiconductor light-emitting structure of an embodiment of the disclosure includes a first-type doped semiconductor layer, a second-type doped semiconductor layer, a light-emitting layer, a first electrode, a second electrode, and a magnetic layer. The light-emitting layer is disposed between the first-type doped semiconductor layer and the second-type doped semiconductor layer. The first electrode is electrically connected to the first-type doped semiconductor layer, and the second electrode is electrically connected to the second-type doped semiconductor layer. The magnetic layer connects the first electrode and the first-type doped semiconductor layer, wherein the valence electron number of at least one doping element doped in the magnetic layer is greater than the valence electron number of at least one element in the host material of the magnetic layer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional schematic of a semiconductor light-emitting structure of an embodiment of the disclosure.

FIG. 2 is a graph of optical power with respect to current density of the semiconductor light-emitting structure of FIG. 1 and a light-emitting diode without a magnetic layer.

FIG. 3A is an experimental graph of electroluminescence intensity with respect to wavelength of the semiconductor light-emitting structure of FIG. 1 and a light-emitting diode without a magnetic layer.

FIG. 3B is a simulation graph of electroluminescence intensity with respect to wavelength of the semiconductor light-emitting structure of FIG. 1 and a light-emitting diode without a magnetic layer.

FIG. 4 is a cross-sectional schematic of a semiconductor light-emitting structure of another embodiment of the disclosure.

FIG. 5 is a cross-sectional schematic of a semiconductor light-emitting structure of yet another embodiment of the disclosure.

FIG. 6 is a cross-sectional schematic of a semiconductor light-emitting structure of still yet another embodiment of the disclosure.

### DETAILED DESCRIPTION OF DISCLOSED EMBODIMENTS

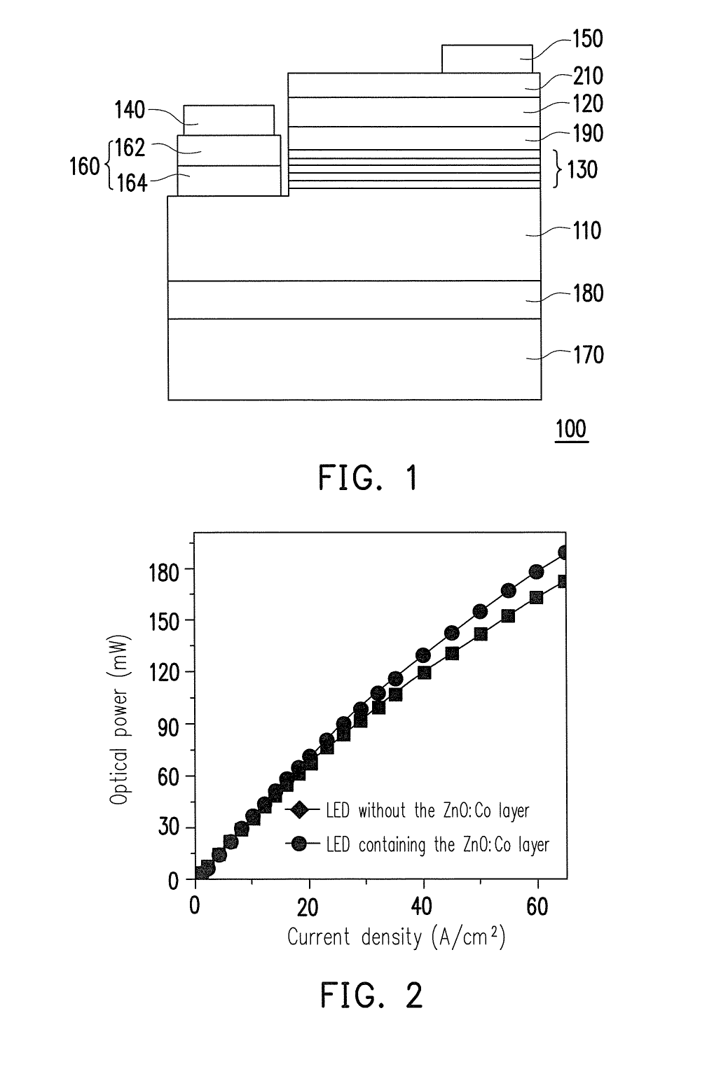

FIG. 1 is a cross-sectional schematic of a semiconductor light-emitting structure of an embodiment of the disclosure. Referring to FIG. 1, a semiconductor light-emitting structure 100 of the present embodiment includes a first-type doped semiconductor layer 110, a second-type doped semiconductor layer 120, a light-emitting layer 130, a first electrode 140, a second electrode 150, and a magnetic layer 160. The light-emitting layer 130 is disposed between the first-type doped semiconductor layer 110 and the second-type doped semiconductor layer 120. In the present embodiment, the first-type doped semiconductor layer 110 is an N-type semiconductor layer, and the second-type doped semiconductor layer 120 is a P-type semiconductor layer. However, in other embodiments, the first-type doped semiconductor layer 110 can also be a P-type semiconductor layer, and the second-type doped semiconductor layer 120 can be an N-type semiconductor layer. Moreover, in the present embodiment, the light-emitting layer 130 is, for instance, a multiple quantum well or a quantum well. In the present embodiment, the semiconductor light-emitting structure 100 is a light-emitting diode (LED). In the present embodiment, the material used for each of the first-type doped semiconductor layer 110, the second-type doped semiconductor layer 120, and the light-emitting layer 130 can be a gallium-nitride-based (GaN-based) material, wherein a potential well and an energy barrier of the multiple quantum well can be formed by doping indium (In) of different concentrations.

The first electrode 140 is electrically connected to the first-type doped semiconductor layer 110, and the second electrode 150 is electrically connected to the second-type doped semiconductor layer 120. The magnetic layer 160 connects the first electrode 140 and the first-type doped semiconductor layer 110. In the present embodiment, the second electrode 150 is disposed on the second-type doped semiconductor layer 120. Moreover, in the present embodiment, at least a portion of the magnetic layer 160 is magnetic, and the bandgap of at least another portion of the magnetic layer 160 is greater than 0 electron volt (eV) and is less than or equal to 5 eV, and the material of the magnetic layer 160 includes metal, metal oxide, or a combination thereof. In the present embodiment, the magnetic layer 160 is, for instance, a magnetic semiconductor layer, a doping element is at least doped in the magnetic layer 160, and the valence electron number of the doping element is greater than the valence electron number of at least one element in the host material of the magnetic layer 160. In the present specification, the host material refers to a material of the entire material except the dopant of the entire material, and the mole percentage of each element in the host material with respect to the entire material (such as the material of the magnetic layer 160 in the present specification) is greater than or equal to 7.5%. In the present embodiment, the material of each of the first electrode 140 and the second electrode 150 is, for instance, metal or any other material having high conductivity.

Moreover, in the present embodiment, the magnetic layer 160 is, for instance, a stacked layer, and the magnetic layer 160 includes a magnetic sublayer 162 and conductive sublayer 164, wherein the conductive sublayer 164 is, for instance, a transparent conductive sublayer. The conductive sublayer 164 is disposed between the first-type doped semiconductor layer 110 and the magnetic sublayer 162, and the magnetic sublayer 162 is disposed between the conductive sublayer 164 and the first electrode 140. However, in other embodiments, the magnetic sublayer 162 can also be disposed between the first-type doped semiconductor layer 110 and the conductive sublayer 164, and the conductive sublayer 164 is disposed between the magnetic sublayer 162 and the first electrode 140.

In the present embodiment, the transmittance of the conductive sublayer 164 for light having a wavelength of 450 nanometer (nm) is greater than or equal to 30%, and the bandgap of the conductive sublayer 164 is greater than 0 eV and is less than or equal to 5 eV. In an embodiment, the transmittance of the conductive sublayer 164 for light having a wavelength of 450 nm is, for instance, greater than or equal to 70%. In the present embodiment, the saturation magnetization of the magnetic sublayer 162 is greater than 10⁻⁵ electromagnetic unit (emu). For instance, under room temperature (such as 25° C.), the saturation magnetization of the magnetic sublayer 162 is greater than 10⁻⁵ emu. Moreover, in the present embodiment, the bandgap of the magnetic sublayer 162 is greater than 0 eV, and the bandgap of the magnetic sublayer 162 is less than or equal to 5 eV. In an embodiment, the bandgap of the magnetic sublayer 162 can be greater than 2.5 eV.

In the present embodiment, the material of the magnetic sublayer 162 includes zinc oxide (ZnO) doped with cobalt (Co) and not doped with other intentionally doping elements, or includes ZnO doped with Co and at least another doping element, wherein the “at least another doping element” includes gallium (Ga), aluminum (Al), indium (In), tin (Sn), or a combination thereof. For instance, the material of the magnetic sublayer 162 can be ZnO doped with Ga and Co, ZnO doped with Al and Co, ZnO doped with Ga, Al, and Co, etc. Moreover, in the present embodiment, the material of the conductive sublayer 164 includes ZnO doped with a doping element, wherein the doping element includes Ga, Al, In, Sn, or a combination thereof. For instance, the material of the magnetic sublayer 162 can be ZnO doped with Ga, ZnO doped with Al, ZnO doped with Ga and Al, etc. In particular, Co, Zn, Ga, Al, In, Sn, and O are respectively the element symbols of cobalt, zinc, gallium, aluminum, indium, tin, and oxygen.

In the present embodiment, a doping element is at least doped in the conductive sublayer 164, and the valence electron number of the doping element is greater than the valence electron number of at least one element in the host material of the conductive sublayer 164. In the present embodiment, the mole percentage of each element in the host material of the conductive sublayer with respect to the conductive sublayer is greater than or equal to 7.5%. For instance, the host material of the conductive sublayer 164 is ZnO, the valence electron number of Zn is 2, and therefore a Group IIIA element such as boron (B), Ga, Al, In, or thallium (Tl) having 3 valence electrons can be doped. Moreover, since the valence electron number of 0 of ZnO is 6, a Group VITA element such as fluorine (F), chlorine (Cl), bromine (Br), iodine (I), or astatine (At) having 7 valence electrons can be doped. In particular, the aforementioned dopants are used as electron donors. In the present embodiment, the material of the magnetic layer 160 includes a transition element compound. For instance, the material of the magnetic sublayer 162 can include cobalt (Co). In an embodiment, the mole percentage of Ga in the conductive sublayer 164 can be within the range of 0.1% to 3.5%.

In the present embodiment, the thickness of the conductive sublayer 164 is within the range of 20 nm to 70 nm. In an embodiment, the thickness of the conductive sublayer 164 is, for instance, 30 nm. Moreover, in the present embodiment, the thickness of the magnetic sublayer 162 is within the range of 30 nm to 500 nm. In an embodiment, the thickness of the magnetic sublayer 162 is within the range of 100 nm to 130 nm. For instance, the thickness of the magnetic sublayer 162 is 120 nm.

In the semiconductor light-emitting structure 100 of the present embodiment, since the bandgap of at least another portion of the magnetic layer 160 is greater than 0 eV and is less than or equal to 5 eV, or since the valence electron number of at least one doping element doped in the magnetic layer 160 is greater than the valence electron number of at least one element in the host material of the magnetic layer 160, or since the magnetic layer 160 includes the magnetic sublayer 162 and the transparent conductive sublayer 164, the semiconductor light-emitting structure 100 can have higher luminous efficiency while maintaining a lower operating voltage. When an electron from the first electrode 140 passes through the magnetic sublayer 162, a carrier-mediated magnetic interaction is generated by the electron and the magnetic moment within the magnetic sublayer 162, such that the mobility of the electron is reduced before entering the light-emitting layer 130 (i.e., multiple quantum well). In general, if the magnetic sublayer 162 is not used, then the mobility of an electron is greater than that of an electron hole. Accordingly, a portion of electrons move too fast, such that the electrons only recombine with the electron holes in the second-type doped semiconductor layer 120 after passing through the light-emitting layer 130. Such recombination does not emit light. However, in the present embodiment, since the mobility of the electrons is reduced via the magnetic sublayer 162, most of the electrons are recombined with the electron holes in the light-emitting layer 130 so as to emit light. As a result, the luminous efficiency of the semiconductor light-emitting structure 100 can be increased.

Moreover, when the magnetic sublayer 162 is added, the forward voltage (V_{F}) of the semiconductor light-emitting structure 100 is increased, such that the operating voltage of the semiconductor light-emitting structure 100 is increased. Therefore, in the present embodiment, the conductive sublayer 164 is adopted, and the valence electron number of at least one doping element doped in the conductive sublayer 164 is made greater than the valence electron number of at least one element in the host material of the conductive sublayer 164. As a result, contact resistance can be effectively reduced, thus reducing the forward voltage and operating voltage of the semiconductor light-emitting structure 100. In this way, the semiconductor light-emitting structure 100 can effectively increase luminous efficiency while maintaining a lower forward voltage.

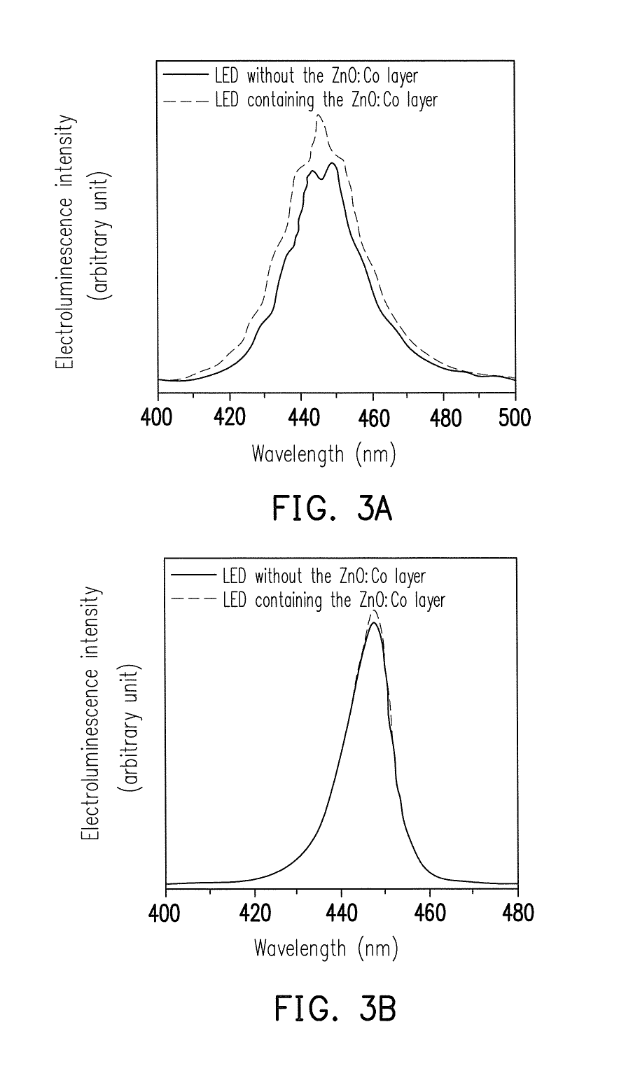

FIG. 2 is a graph of optical power with respect to current density of the semiconductor light-emitting structure of FIG. 1 and a light-emitting diode without a magnetic layer, FIG. 3A is an experimental graph of electroluminescence intensity with respect to wavelength of the semiconductor light-emitting structure of FIG. 1 and a light-emitting diode without a magnetic layer, and FIG. 3B is a simulation graph of electroluminescence intensity with respect to wavelength of the semiconductor light-emitting structure of FIG. 1 and a light-emitting diode without a magnetic layer. Referring to FIG. 1, FIG. 2, FIG. 3A, and FIG. 3B, in the experiments of FIG. 2 and FIG. 3A and in the simulation of FIG. 3B, the material of the magnetic sublayer 162 of the magnetic layer 160 of the semiconductor light-emitting structure 100 adopts ZnO doped with Co, the material of the conductive sublayer 164 adopts ZnO doped with Ga, and it is apparent from FIG. 2, FIG. 3A, and FIG. 3B that, the semiconductor light-emitting structure 100 adopting the magnetic layer 160 of the present embodiment has higher luminous efficiency.

In an embodiment, the mole percentage of Co in the ZnO material doped with Co used in the magnetic sublayer 162 is, for instance, about 7%, the thickness of the magnetic sublayer 162 is, for instance, 120 nm, the mole percentage of Ga in the ZnO material doped with Ga used in the conductive sublayer 164 is, for instance, about 3.5%, and the thickness of the conductive sublayer 164 is, for instance, 30 nm. In an embodiment, the perpendicular distance from the lower surface of the magnetic layer 160 to the lower surface of the first-type doped semiconductor layer 110 can be greater than 700 nm.

TABLE 1

| | Average | Average | Average | Average |
|---|---|---|---|---|
| | optical | forward | optical power | forward voltage |
| Form | power | voltage | difference (%) | difference (%) |
| No magnetic layer | 15.20 | 5.99 | 0 | 0 |
| Single ZnO: Co | 17.95 | 6.96 | 18.09 | 16.19 |
| layer | | | | |
| Single ZnO: Ga | 15.28 | 5.37 | 0.53 | −10.35 |
| layer | | | | |
| ZnO: Co layer + | 18.04 | 5.49 | 18.68 | −8.35 |
| ZnO: Ga layer | | | | |

Table 1 lists experimental parameter values of various forms of a semiconductor light-emitting structure. In particular, “no magnetic layer” refers to a semiconductor light-emitting structure for which a magnetic layer is not disposed between the first electrode 140 and the first-type doped semiconductor layer 110; “single ZnO:Co layer” refers to a semiconductor light-emitting structure for which a single ZnO layer doped with Co is disposed between the first electrode 140 and the first-type doped semiconductor layer 110; “single ZnO:Ga layer” refers to a semiconductor light-emitting structure for which a single ZnO layer doped with Ga is disposed between the first electrode 140 and the first-type doped semiconductor layer 110; “ZnO:Co layer+ZnO:Ga layer” refers to the semiconductor light-emitting structure 100 of the present embodiment, wherein the magnetic layer 160 is disposed between the first electrode 140 and the first-type doped semiconductor layer 110, the magnetic layer 160 includes the magnetic sublayer 162 and the conductive sublayer 164, the material of the magnetic sublayer 162 is ZnO doped with Co, and the material of the conductive sublayer 164 is ZnO doped with Ga. Moreover, “average optical power” and “average forward voltage” refer to average values obtained from a plurality of semiconductor light-emitting structures 100 in the experiment, and “average optical power difference (%)” (or “average forward voltage difference (%)”) refers to the percentage value obtained by first subtracting the average optical power (or average forward voltage) of the “no magnetic layer” row from the average optical power (or average forward voltage) of the row, and then dividing by the average optical power (or average forward voltage) of the “no magnetic layer” row.

It is apparent from Table 1 that, when a single ZnO:Co layer is used, although the average optical power is increased by 18.09%, the forward voltage of the semiconductor light-emitting structure is also increased by 16.19%, and therefore the needed operating voltage is too high, thus causing higher power consumption and worse applicability. Moreover, when a single ZnO:Ga layer is used, although the average forward voltage is reduced by 10.35%, the average optical power is barely increased (only by 0.53%). Therefore, the optical power of the semiconductor light-emitting structure still cannot be effectively increased. In comparison, in the present embodiment, with respect to the light-emitting diode without the magnetic layer 160 (i.e., “no magnetic layer” listed in Table 1), the output optical power provided by the semiconductor light-emitting structure 100 of the present embodiment is 18.68% greater, and the operating voltage is 8.35% less. In other words, the operating voltage can even be lower than the light-emitting diode without the magnetic layer 160, and the output optical power can also be effectively increased. In this way, the semiconductor light-emitting structure 100 of the present embodiment can have higher brightness and better applicability.

In an embodiment, the thickness of the magnetic sublayer 162 can be within the range of 30 nm to 500 nm, the mole percentage of Co in ZnO doped with Ga and Co or the ZnO material doped with Co used in the magnetic sublayer 162 is, for instance, within the range of 1% to 3%, the perpendicular distance from the lower surface of the magnetic layer 160 to the lower surface of the first-type doped semiconductor layer 110 can be greater than 1 micron, and the mole percentage of 0 in ZnO doped with Ga and Co or the ZnO material doped with Co used in the magnetic sublayer 162 is, for instance, within the range of 45% to 65%. Moreover, for the ZnO material doped with Ga and Co used in the magnetic sublayer 162, the mole percentage of Ga with respect to the sum of Ga, Co, and Zn is less than 10%, and the mole percentage of Co with respect to the sum of Ga, Co, and Zn is greater than 3%.

In the present embodiment, the semiconductor light-emitting structure 100 can further include a substrate 170, a buffer layer 180, an electron-blocking layer (EBL) 190, and a transparent conductive layer 210. The buffer layer 180 is disposed on the substrate 170, and the first-type doped semiconductor layer 110 is disposed on the buffer layer 180. In the present embodiment, the material of the substrate 170 can be sapphire or other suitable materials, and the material of the buffer layer 180 is, for instance, gallium nitride. The EBL 190 is disposed between the light-emitting layer 130 and the second-type doped semiconductor layer 120 to facilitate the recombination of electrons with electron holes in the light-emitting layer 130, so as to increase the luminous efficiency of the semiconductor light-emitting structure 100. In the present embodiment, the material of the EBL 190 is, for instance, aluminum gallium nitride, aluminum indium gallium nitride, or aluminum indium nitride. The transparent conductive layer 210 is disposed between the second electrode 150 and the second-type doped semiconductor layer 120 to reduce the contact resistance between the second electrode 150 and the second-type doped semiconductor layer 120. In the present embodiment, the material of the transparent conductive layer 210 is, for instance, indium tin oxide (ITO) or other suitable materials.

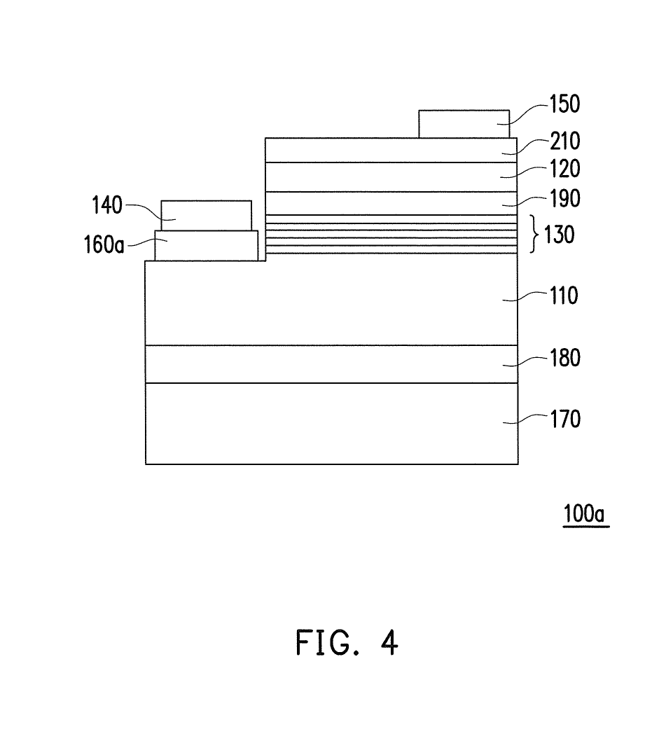

FIG. 4 is a cross-sectional schematic of a semiconductor light-emitting structure of another embodiment of the disclosure. Referring to FIG. 4, a semiconductor light-emitting structure 100a of the present embodiment is similar to the semiconductor light-emitting structure 100 of FIG. 1, and the difference of the two is as described below. In the semiconductor light-emitting structure 100a of the present embodiment, a magnetic layer 160a is a single layer. In the present embodiment, the magnetic layer 160a is magnetic, and the bandgap of the magnetic layer 160a is greater than 0 eV and is less than or equal to 5 eV, and the material of the magnetic layer 160a includes metal, metal oxide, or a combination thereof. In an embodiment, the bandgap of the magnetic layer 160a is greater than 2.5 eV. In the present embodiment, the magnetic layer 160a is, for instance, a magnetic semiconductor layer, a doping element is at least doped in the magnetic layer 160a, and the valence electron number of the doping element is greater than the valence electron number of at least one element in the host material of the magnetic layer 160a.

In the present embodiment, the transmittance of the magnetic layer 160a for light having a wavelength of 450 nm is greater than or equal to 30%, and the bandgap of the magnetic layer 160a is greater than 0 eV and is less than or equal to 5 eV. In an embodiment, the transmittance of the magnetic layer 160a for light having a wavelength of 450 nm is, for instance, greater than or equal to 60%. In the present embodiment, the saturation magnetization of the magnetic layer 160a is greater than 10⁻⁵ emu. For instance, under room temperature (such as 25° C.), the saturation magnetization of the magnetic layer 160a is greater than 10⁻⁵ emu.

In the present embodiment, the material of the magnetic layer 160a includes a transition element compound. For instance, the material of the magnetic layer 160a can include cobalt (Co).

In the present embodiment, the material of the magnetic layer 160a includes ZnO doped with Co and at least another doping element, wherein the “at least another doping element” includes Ga, Al, In, Sn, or a combination thereof. For instance, the material of the magnetic layer 160a can be ZnO doped with Ga and Co, ZnO doped with Al and Co, ZnO doped with Ga, Al, and Co, etc. In an embodiment, the mole percentage of Co in the magnetic layer 160a is, for instance, about 7%. In an embodiment, the mole percentage of Ga in the magnetic layer 160a is, for instance, within the range of 0.1% to 3.5%. In the present embodiment, the thickness of the magnetic layer 160a is within the range of 100 nm to 130 nm. In an embodiment, the thickness of the conductive layer 160a is, for instance, 120 nm.

In the present embodiment, since a single layer of the magnetic layer 160a has both the transition element Co and the electron donor Ga, the luminous efficiency can be effectively increased while maintaining a lower forward voltage.

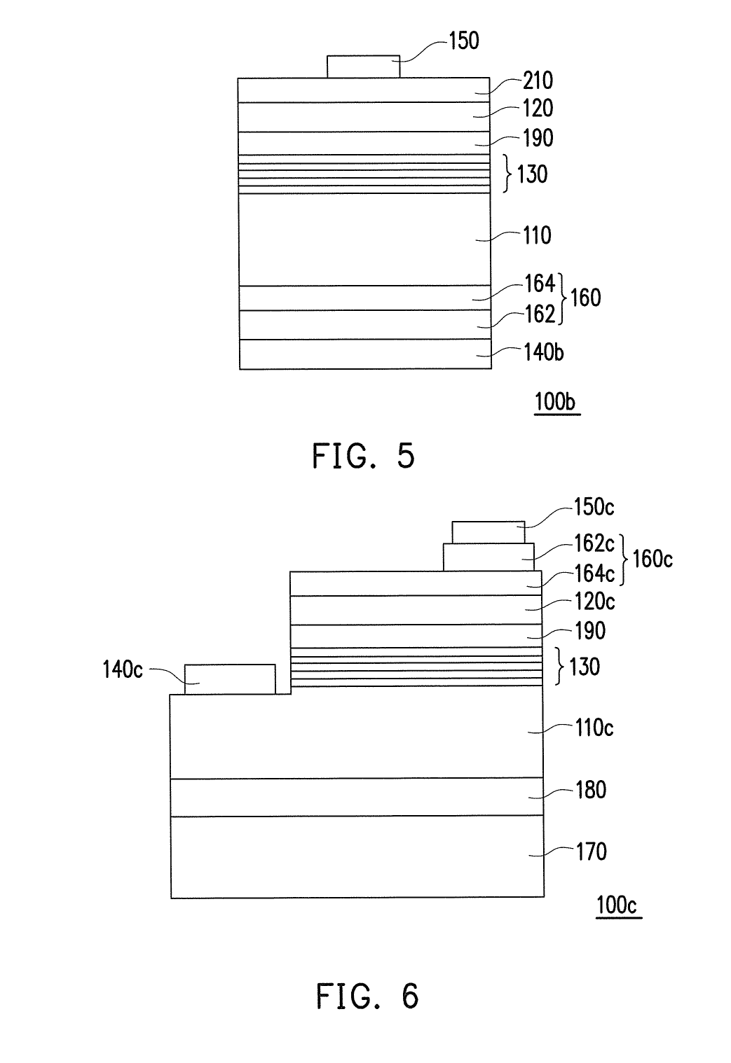

FIG. 5 is a cross-sectional schematic of a semiconductor light-emitting structure of yet another embodiment of the disclosure. Referring to FIG. 5, a semiconductor light-emitting structure 100b of the present embodiment is similar to the semiconductor light-emitting structure 100 of FIG. 1, and the difference of the two is as described below. The semiconductor light-emitting structure 100 of FIG. 1 is a horizontal light-emitting diode structure. That is, the first electrode 140 and the second electrode 150 are located on the same side of the semiconductor light-emitting structure 100. However, the semiconductor light-emitting structure 100b of the present embodiment is a vertical light-emitting diode structure. That is, a first electrode 140b and the second electrode 150 are located on two opposite sides of the semiconductor light-emitting structure 100b. The magnetic layer 160 can be disposed on the lower surface of the first-type doped semiconductor layer 110, and the first electrode 140b is a conductive layer disposed on the lower surface of the magnetic layer 160. In other embodiments, the magnetic layer 160 in FIG. 5 can also be replaced by a single layer of the magnetic layer 160a in FIG. 4.

FIG. 6 is a cross-sectional schematic of a semiconductor light-emitting structure of still yet another embodiment of the disclosure. Referring to FIG. 6, a semiconductor light-emitting structure 100c of the present embodiment is similar to the semiconductor light-emitting structure 100 of FIG. 1, and the difference of the two is as described below. In the semiconductor light-emitting structure 100c of the present embodiment, a first-type doped semiconductor layer 120c is a P-type semiconductor layer disposed between a first electrode 150c and the EBL 190, and a second-type doped semiconductor layer 110c is an N-type semiconductor layer disposed between the substrate 170 and the light-emitting layer 130. In other words, a magnetic layer 160c is disposed between the P-type semiconductor layer (i.e., first-type doped semiconductor layer 120c) and the first electrode 150c. In the present embodiment, a magnetic sublayer 162c of the magnetic layer 160c is disposed between the first electrode 150c and a conductive sublayer 164c, and the conductive sublayer 164c is disposed between the magnetic sublayer 162c and the first-type doped semiconductor layer 120c.

In other embodiments, the magnetic layer 160c in FIG. 6 can also be replaced by a single layer of the magnetic layer 160a in FIG. 4.

Based on the above, in the semiconductor light-emitting structure of the embodiments of the disclosure, since the bandgap of at least another portion of the magnetic layer is greater than 0 eV and is less than or equal to 5 eV, or since the valence electron number of at least one doping element doped in the magnetic semiconductor layer is greater than the valence electron number of at least one element in the host material of the magnetic layer, or since the stacked layer includes a magnetic sublayer and a transparent conductive sublayer, the semiconductor light-emitting structure can have higher luminous efficiency while maintaining a lower operating voltage.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A semiconductor light-emitting structure, comprising:
a first-type doped semiconductor layer;
a second-type doped semiconductor layer;
a light-emitting layer disposed between the first-type doped semiconductor layer and the second-type doped semiconductor layer;
a first electrode electrically connected to the first-type doped semiconductor layer;
a second electrode electrically connected to the second-type doped semiconductor layer; and
a magnetic layer connecting the first electrode and the first-type doped semiconductor layer, wherein at least a portion of the magnetic layer is magnetic, and a bandgap of at least another portion of the magnetic layer is greater than 0 eV and is less than or equal to 5 eV, and a material of the magnetic layer comprises metal, metal oxide, or a combination thereof.

2. The semiconductor light-emitting structure of claim 1, wherein the magnetic layer comprises a stacked magnetic sublayer and conductive sublayer, a doping element is at least doped in the conductive sublayer, a valence electron number of the doping element is greater than a valence electron number of at least one element in a host material of the conductive sublayer.

3. The semiconductor light-emitting structure of claim 2, wherein a mole percentage of each element in the host material of the conductive sublayer with respect to the conductive sublayer is greater than or equal to 7.5%.

4. The semiconductor light-emitting structure of claim 1, wherein the magnetic layer comprises a stacked magnetic sublayer and conductive sublayer, and a saturation magnetization of the magnetic sublayer is greater than 10⁻⁵ emu.

5. The semiconductor light-emitting structure of claim 1, wherein the magnetic layer is a single layer, and a saturation magnetization of the magnetic layer is greater than 10⁻⁵ emu.

6. The semiconductor light-emitting structure of claim 1, wherein the first-type doped semiconductor layer is an N-type semiconductor layer, and the second-type doped semiconductor layer is a P-type semiconductor layer.

7. A semiconductor light-emitting structure, comprising:
a first-type doped semiconductor layer;
a second-type doped semiconductor layer;
a light-emitting layer disposed between the first-type doped semiconductor layer and the second-type doped semiconductor layer;
a first electrode electrically connected to the first-type doped semiconductor layer;
a second electrode electrically connected to the second-type doped semiconductor layer; and
a magnetic layer connecting the first electrode and the first-type doped semiconductor layer, wherein a valence electron number of at least one doping element doped in the magnetic layer is greater than a valence electron number of at least one element in a host material of the magnetic layer.

8. The semiconductor light-emitting structure of claim 7, wherein the magnetic layer comprises a stacked magnetic sublayer and conductive sublayer, a transmittance of the conductive sublayer for light having a wavelength of 450 nm is greater than or equal to 30%, and a bandgap of the conductive sublayer is greater than 0 eV and is less than or equal to 5 eV.

9. The semiconductor light-emitting structure of claim 7, wherein the magnetic layer comprises a stacked magnetic sublayer and conductive sublayer, a valence electron number of at least one doping element doped in the conductive sublayer is greater than a valence electron number of at least one element in a host material of the conductive sublayer.

10. The semiconductor light-emitting structure of claim 7, wherein the magnetic layer is a single layer, and a saturation magnetization of the magnetic layer is greater than 10⁻⁵ emu.

11. The semiconductor light-emitting structure of claim 7, wherein the first-type doped semiconductor layer is an N-type semiconductor layer, and the second-type doped semiconductor layer is a P-type semiconductor layer.

12. The semiconductor light-emitting structure of claim 7, wherein the at least one doping element comprises a Group IIIA element, a Group VIIA element, or a combination thereof.

13. The semiconductor light-emitting structure of claim 12, wherein the Group IIIA element comprises gallium, and a mole percentage of gallium in the magnetic layer is within a range of 0.1% to 3.5%.

14. The semiconductor light-emitting structure of claim 7, wherein a mole percentage of each element in the host material of the magnetic layer with respect to the magnetic layer is greater than or equal to 7.5%.
